(19) United States
(12) Patent Application Publication
(10) Pub. No.: US 2020/0328253 A1
(43) Pub. Date: Oct. 15, 2020

(54) METAL-INSULATOR-SEMICONDUCTOR (MIS) RESISTIVE RANDOM ACCESS MEMORY (RRAM) (MIS RRAM) DEVICES AND MIS RRAM BIT CELL CIRCUITS, AND RELATED METHODS OF FABRICATING

(71) Applicant: QUALCOMM Incorporated, San Diego, CA (US)

(72) Inventors: Bin Yang, San Diego, CA (US); Xia Li, San Diego, CA (US); Guoqing Chen, San Diego, CA (US)

(21) Appl. No.: 16/382,904

(22) Filed: Apr. 12, 2019

(51) Int. Cl. H01L 27/24; H01L 45/00; H01L 29/78; G11C 13/00; H01L 29/66; H01L 29/08; H01L 29/51; H01L 21/265

(52) U.S. Cl. CPC H01L 27/2436; H01L 21/31111; H01L 45/146; H01L 45/1233; H01L 29/7851; G11C 13/004; H01L 45/1608; H01L 29/66795; H01L 29/0847; H01L 29/517; H01L 45/08; H01L 21/26513; H01L 29/66545; H01L 29/6656; G11C 13/0007; G11C 2013/0045; H01L 45/1253

(57) ABSTRACT

A metal-insulator-semiconductor (MIS) resistive random access memory (RRAM) (MIS RRAM) device and MIS RRAM bit cell circuit are disclosed. A RRAM bit cell includes a RRAM device that can store a memory state and an access transistor to control access to the RRAM device. The RRAM device stores data as an electrical resistance formed in an oxide layer by applying a voltage differential between the top and bottom electrodes through the access transistor to generate an electric field in the oxide layer. This structure is similar to a metal gate formed over a channel region of a transistor. Forming the bottom electrode of the MIS RRAM device in a semiconductor structure may allow the dimensions of the electrodes of the MIS RRAM device to be scaled down to the dimensions of a transistor gate, because the MIS RRAM device structure can be fabricated with the transistor in a compatible process.

### BACKGROUND

### I. Field of the Disclosure

The technology of the disclosure relates generally to resistive random access memory (RRAM) devices, wherein the RRAM device can be employed in a memory bit cell circuit in a memory system to store a memory state as an electrical resistance.

### II. Background

Integrated circuits (ICs) in computing devices read data from and write data to memory devices during normal operation. Memory devices vary with respect to several performance characteristics, and these performance characteristics are considered to determine the best type of memory for a particular application or device. These characteristics include data access time, read/write cycling endurance, data retention duration, power consumption, operating voltage, density, and cost. Data accessed more frequently is typically stored in a faster form of memory device, but faster memory devices typically consume higher power than slower forms of memory devices. Non-volatile memory (NVM) includes types of memory that are capable of storing data for a long period of time with little or no power provided, but the time to read or write NVM may be longer than desired for applications in which data is frequently accessed by a processor.

Resistive random access memory (RRAM) has become popular, because it is a NVM with significantly faster performance and lower energy utilization than other types of NVMs. The combination of higher performance and lower energy utilization particularly increases the attractiveness of RRAM devices for use in mobile devices that rely on battery power. Data is stored in an RRAM device as a memory state defined by either setting the RRAM device into a low-resistance state (LRS) or resetting the RRAM device into a high-resistance state (HRS). The LRS or HRS is determined by an electrical resistance between a top electrode and a bottom electrode. The RRAM device may be switched back and forth between the LRS and HRS by controlled application of a voltage across the top and bottom electrode. This voltage creates an electric field in an oxide layer disposed between the top and bottom electrodes. In response to a first voltage, mobile defects or vacancies, created by oxygen ions or other species of mobile ions (e.g., tantalum (Ta), titanium (Ti), hafnium (Hf) or manganese (Mn), for example) in an oxide layer, can migrate to form a low-resistance path (i.e., filament) between the top and bottom electrodes to attain the LRS. In response to a second voltage of a different magnitude and/or polarity than the first voltage, the filament can be broken by dispersing some of the defects to restore the RRAM device to the HRS. In a conventional metal-insulator-metal (MIM) structure, the top electrode and bottom electrode are formed of adjacent layers of metal by a photolithographic process in a back-end-of-line (BEOL) fabrication stage. The ever-increasing push to store more data in a smaller space has driven efforts to increase memory density by scaling down device dimensions, but scaling down the area occupied by an RRAM device requires top and bottom electrodes to have smaller area. However, the minimum area (minimum length and width) of the top electrode and the bottom electrode of a MIM RRAM structure is limited by existing photolithography process capability, as well as the need to meet length and width variation margin requirements for a stable manufacturing window to ensure stable RRAM operation and yield.

A schematic diagram of a RRAM bit cell circuit 100, including an RRAM device 102 and an access transistor 104, is shown in FIG. 1A. A voltage applied between a top electrode 106 and a bottom electrode 108 of the RRAM device 102 is controlled by the access transistor 104. A source line (SL) provides a source line voltage V_{SL} to a source region 110 of the access transistor 104. The source line voltage V_{SL} is passed to the drain region 112 of the access transistor 104 in response to a word line voltage V_{WL} on a word line (WL) coupled to a gate 114 of the access transistor 104 to turn on the access transistor 104. A bit line (BL) is coupled to the top electrode 106. The drain region 112 of the access transistor 104 is coupled to the bottom electrode 108 of the RRAM device 102. A voltage difference between the source line voltage V_{SL} and a bit line voltage V_{BL} on the bit line BL may be used to read, set, or reset the resistance state of the RRAM device 102. The RRAM device 102 shown in a cross-sectional view in FIG. 1A includes an oxide layer 116 disposed between the top electrode 106 and the bottom electrode 108 in a MM structure.

FIG. 1B is an illustration of a cross-sectional side view of a metal-insulator-metal (MIM) RRAM bit cell circuit 120 formed in a conventional fabrication process. The operation of the MIM RRAM bit cell circuit 120 is just as described above with regard to the RRAM bit cell circuit 100. The MIM RRAM bit cell circuit 120 includes a MIM RRAM device 122 and an access transistor 124. In a conventional front-end-of-line (FEOL) process, the access transistor 124 in the example in FIG. 1B is fabricated as a metal-oxide semiconductor (MOS) field-effect transistor (FET) (MOSFET) with an N+ doped source region 126 and an N+ doped drain region 128 separated by a channel region 130 of a semiconductor 132. The word line WL is coupled to a gate 134 of the access transistor 124. The MIM RRAM device 122 and circuit interconnects to the MIM RRAM bit cell circuit 120 are formed in a BEOL process. Here, the source line SL is provided at the second metal layer (M2) and coupled to the source region 126 of the access transistor 124 by vias V connecting through the first metal layer (M1). When a voltage is applied to the word line WL, the access transistor 124 is turned on, and the source line voltage V_{SL} is coupled to the drain region 128.

The MIM RRAM device 122 is also formed in the BEOL process as part of an RRAM array which employs a cross-bar architecture, for example. The MIM RRAM device 122 is formed by disposing an oxide layer 136 between overlapping lines in the third metal layer (M3) and the fourth metal layer (M4). A bottom electrode 138 is formed on the third metal layer (M3), which has metal lines extending in a first direction, and a top electrode 140 is formed on the fourth metal layer (M4), which has metal lines extending in a second direction orthogonal to the first direction. The area of the MIM RRAM 122 device is determined by dimensions of the overlapping lines in the M3 and M4 metal layers. The bottom electrode 138 is coupled down to the drain region 128 of the access transistor 124 by vias V2 through M2 and M. The metal line in the M4 layer forming the top electrode 140 may be the bit line BL. Scaling down the MIM RRAM device 122 would require reducing the minimum area (e.g., narrowing the minimum length and/or width) of the top and bottom electrodes of a MIM RRAM structure. Reducing the minimum area of the electrodes of a RRAM device is limited by existing photolithography process capability, as well as the need to meet length and width variation margin requirements for a stable manufacturing window to ensure stable RRAM operation and yield.

### SUMMARY OF THE DISCLOSURE

Aspects disclosed herein include a metal-insulator-semiconductor (MIS) resistive random access memory (RRAM) (MIS RRAM) device and MIS RRAM bit cell circuit. A method of fabricating a MIS RRAM bit cell circuit including the MIS RRAM device is also disclosed. A RRAM bit cell includes a RRAM device that can store a memory state and an access transistor to control access to the RRAM device. The RRAM device stores data as an electrical resistance formed in an oxide layer between a bottom electrode and a top electrode. Data is stored by applying a voltage differential between the top and bottom electrodes through the access transistor to generate an electric field in the oxide layer. A first electric field can induce mobile defects in the oxide layer to form a cluster providing a low-resistance path between the top and bottom electrodes. In response to a second electric field, the low-resistance cluster may be at least partially dispersed. In exemplary aspects disclosed herein, the top electrode of the MIS RRAM device is disposed in a metal layer, whereas the bottom electrode is disposed in a semiconductor structure as opposed to a metal layer. This structure is similar, for example, to a metal gate formed over a channel region of a transistor. Forming the bottom electrode of the MIS RRAM device in a semiconductor structure may allow the dimensions of the electrodes of the MIS RRAM device to be scaled down to the dimensions of a transistor gate, because the MIS RRAM device structure can be fabricated with the transistor in a compatible process. As a result, the size of an array of MIS RRAM bit cell circuits, and power consumption of a MIS RRAM array can be significantly reduced compared to a conventional MIM RRAM array. In addition, the MIS RRAM device and access transistor of a MIS RRAM bit cell circuit can be fabricated together in an integrated front-end-of-line (FEOL) process. Conventionally, the top and bottom electrodes of a RRAM device are formed in metal layers in a back-end-of-line (BEOL) process, and scaling is limited by existing photolithography process capability (minimum area rule) as well as the width and length margin requirements for a stable manufacturing yield window.

In this regard, in one aspect, a MIS RRAM device is disclosed. The MIS RRAM device includes a first electrode including a doped region of a semiconductor structure. The MIS RRAM device also includes an oxide layer disposed on the doped region. The MIS RRAM device also includes a second electrode including a metal layer disposed on the oxide layer. The oxide layer is configured to be reversibly set in a low-resistance state (LRS) or a high-resistance state (HRS) in response to a voltage differential between the first electrode and the second electrode.

In another aspect, a MIS RRAM bit cell circuit is disclosed. The MIS RRAM bit cell circuit includes a MIS RRAM device in a first semiconductor structure on a substrate. The MIS RRAM device includes a first electrode including a doped region of the first semiconductor structure. The MIS RRAM device also includes an oxide layer disposed on the doped region. The MIS RRAM device also includes a second electrode including a first metal layer disposed on the oxide layer. The MIS RRAM bit cell circuit also includes an access transistor in a second semiconductor structure on the substrate. The access transistor includes a first source/drain region of the second semiconductor structure configured to couple to a source line. The access transistor also includes a second source/drain region of the second semiconductor structure coupled to first electrode of the MIS RRAM device. The access transistor also includes a channel region of the second semiconductor structure disposed between the first source/drain region and the second source/drain region. The access transistor also includes a gate including a second metal layer disposed in the channel region. The gate is configured to be coupled to a word line. The access transistor is configured to supply a voltage on the source line to the first electrode in response to a voltage on the word line.

In another aspect, a method of fabricating a MIS RRAM bit cell circuit is disclosed. The method includes forming a first electrode of a MIS RRAM device including a doped region of a first semiconductor structure on a substrate. The method also includes forming a first source/drain region and a second source/drain region at respective end portions of a channel region of a transistor in a second semiconductor structure on the substrate. The method also includes disposing a gate dielectric layer on the channel region of the transistor in the second semiconductor structure. The method also includes disposing an oxide layer on the first electrode of the MIS RRAM device in the first semiconductor structure. The method also includes disposing a metal layer on the first and second semiconductor structures, the metal layer forming a second electrode of the MIS RRAM device on the oxide layer, and a gate of the transistor on the gate dielectric layer.

In another aspect, a memory array is disclosed. The memory array includes a plurality of MIS RRAM bit cell circuits. Each of the plurality of MIS RRAM bit cell circuits includes a MIS RRAM device in a first semiconductor structure on a substrate. The MIS RRAM device includes a first electrode including a doped region of the first semiconductor structure. The MIS RRAM device also includes an oxide layer disposed on the doped region. The MIS RRAM device also includes a second electrode including a first metal layer disposed on the oxide layer and configured to be coupled to a bit line. Each of the plurality of MIS RRAM bit cell circuits also includes an access transistor in a second semiconductor structure on the substrate. The access transistor includes a first source/drain region of the second semiconductor structure configured to couple to a source line. The access transistor also includes a second source/drain region of the second semiconductor structure coupled to the first electrode of the MIS RRAM device. The access transistor also includes a channel region of the second semiconductor structure disposed between the first source/drain region and the second source/drain region. The access transistor also includes a gate including a second metal layer disposed on the channel region, the gate configured to be coupled to a word line. The access transistor is configured to supply a voltage on the source line to the bottom electrode in response to a voltage on the word line. The memory array also includes array access circuits configured to provide a word line voltage on the word line, a source line voltage on the source line, and a bit line voltage on the bit line to read or store data in at least one of the plurality of MIS RRAM bit cell circuits in response to the word line voltage.

### BRIEF DESCRIPTION OF THE FIGURES

FIG. 1A is a schematic view of a resistive random access memory (RRAM) bit cell circuit illustrating the layers of a RRAM device and a schematic depiction of a field-effect transistor (FET)-type access transistor to control access to an electrode of the RRAM device;

FIG. 1B is a cross-sectional side view of a conventional metal-insulator-metal (MIM) RRAM bit cell circuit including the semiconductor and metal layers of an integrated circuit (IC) in which a FET and a MIM RRAM device are formed;

FIG. 2 is a cross-sectional side view of an exemplary metal-insulator-semiconductor (MIS) RRAM bit cell circuit in which a top electrode is formed in a metal layer over a bottom electrode disposed in a semiconductor structure, allowing dimensions of the electrodes of a MIS RRAM device to be scaled down to the dimensions of a transistor gate, because the MIS RRAM device can be fabricated with the access transistor in a compatible process;

FIG. 3 is a flowchart illustrating an exemplary process for fabricating the MIS RRAM bit cell circuit in FIG. 2, including forming the MIS RRAM device in a first semiconductor structure and an access transistor in a second semiconductor structure in an integrated complementary metal-oxide semiconductor (CMOS)-compatible front-end-of-line (FEOL) process;

FIGS. 4A-4R illustrate exemplary fabrication stages of fabricating the MIS RRAM bit cell circuit in FIG. 2 according to the exemplary process illustrated in FIG. 3, including forming a MIS RRAM device in a first semiconductor structure and an access transistor in a second semiconductor structure in an integrated CMOS-compatible FEOL process;

FIG. 5 is a schematic diagram of an exemplary MIS RRAM array comprising a plurality of MIS RRAM bit cell circuits organized in rows and columns, and circuitry for accessing the MIS RRAM bit cell circuits, wherein each MIS RRAM bit cell circuit includes a MIS RRAM device in which a top electrode is formed in a metal layer over a bottom electrode disposed in a semiconductor structure, allowing dimensions of the electrodes of the MIS RRAM device to be scaled down to the dimensions of a transistor gate, including, but not limited to, the MIS RRAM bit cell circuit in FIG. 2 and FIG. 4R;

FIG. 6 is a block diagram of an exemplary processor-based system that can include a memory employing a MIS RRAM bit cell circuit that includes a MIS RRAM device in which a top electrode is formed in a metal layer over a bottom electrode disposed in a semiconductor structure, allowing dimensions of the electrodes of the MIS RRAM device to be scaled down to the dimensions of a transistor gate, including, but not limited, to the MIS RRAM bit cell circuit in FIG. 2 and FIG. 4R; and

FIG. 7 is a block diagram of an exemplary wireless communications device that includes radio frequency (RF) components formed in an IC, wherein any of the components therein can include a MIS RRAM bit cell circuit that includes a MIS RRAM device in which a top electrode is formed in a metal layer over a bottom electrode disposed in a semiconductor structure, allowing dimensions of the electrodes of the MIS RRAM device to be scaled down to the dimensions of a transistor gate, including, but not limited, to the MIS RRAM bit cell circuit in FIG. 2 and FIG. 4R.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a metal-insulator-semiconductor (MIS) resistive random access memory (RRAM) (MIS RRAM) device and MIS RRAM bit cell circuit. A method of fabricating a MIS RRAM bit cell circuit including the MIS RRAM device is also disclosed. A RRAM bit cell includes a RRAM device that can store a memory state and an access transistor to control access to the RRAM device. The RRAM device stores data as an electrical resistance formed in an oxide layer between a bottom electrode and a top electrode. Data is stored by applying a voltage differential between the top and bottom electrodes through the access transistor to generate an electric field in the oxide layer. A first electric field can induce mobile defects in the oxide layer to form a cluster providing a low-resistance path between the top and bottom electrodes. In response to a second electric field, the low-resistance cluster may be at least partially dispersed. In exemplary aspects disclosed herein, the top electrode of the MIS RRAM device is disposed in a metal layer, whereas the bottom electrode is disposed in a semiconductor structure as opposed to a metal layer. This structure is similar, for example, to a metal gate formed over a channel region of a transistor. Forming the bottom electrode of the MIS RRAM device in a semiconductor structure may allow the dimensions of the electrodes of the MIS RRAM device to be scaled down to the dimensions of a transistor gate, because the MIS RRAM device structure can be fabricated with the transistor in a compatible process. As a result, the size of an array of MIS RRAM bit cell circuits, and power consumption of a MIS RRAM array can be significantly reduced compared to a conventional MIM RRAM array. In addition, the MIS RRAM device and access transistor of a MIS RRAM bit cell circuit can be fabricated together in an integrated front-end-of-line (FEOL) process. Conventionally, the top and bottom electrodes of a RRAM device are formed in metal layers in a back-end-of-line (BEOL) process, and scaling is limited by existing photolithography process capability (minimum area rule) as well as the width and length margin requirements for a stable manufacturing yield window.

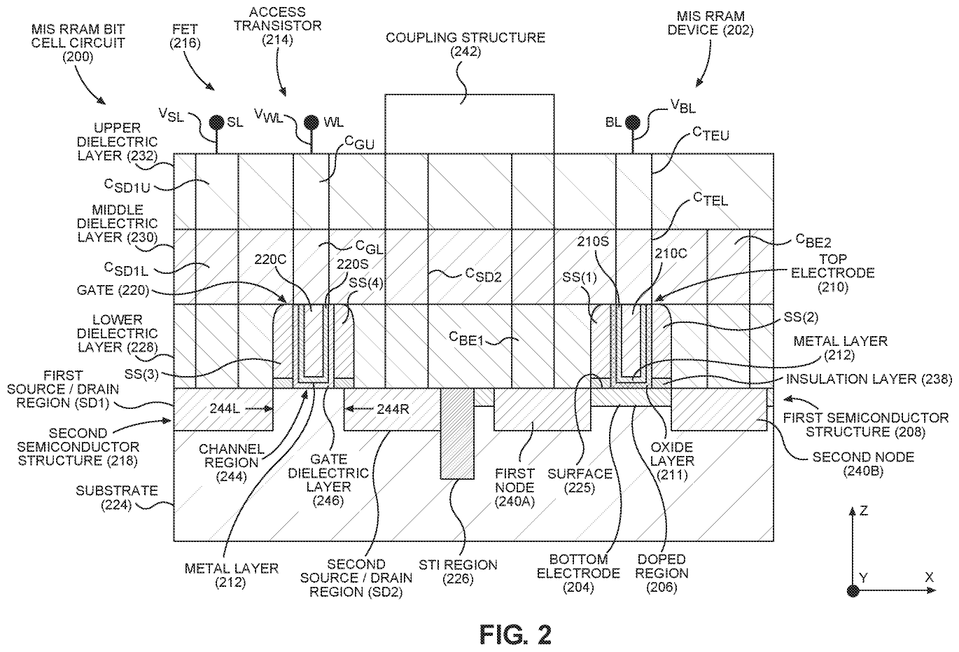

In this regard, FIG. 2 is a cross-sectional side view of an exemplary MIS RRAM bit cell circuit 200 formed in a FEOL complementary metal-oxide semiconductor (CMOS)-compatible process in which formation of a MIS RRAM device 202 is shown. The MIS RRAM device 202 includes a first electrode, which is a bottom electrode 204 comprising a doped region 206 of a first semiconductor structure 208, an oxide layer 211 disposed on the doped region 206, and a second electrode, which is a top electrode 210 of the MIS RRAM device 202 comprising a metal layer 212 disposed on the oxide layer 211. The second electrode or top electrode 210 is further in the Z-axis direction above the substrate 224 than the first electrode or bottom electrode 204. Fabrication of the MIS RRAM device 202 is integrated with formation of an access transistor 214 comprising a field-effect transistor (FET) 216 configured to control supply of voltage to the bottom electrode 204 in a second semiconductor structure 218. Further scaling of conventional metal-insulator-metal (MIM) RRAM devices formed in BEOL processes is limited by existing photolithography process capability, as well as the need to meet length and width variation margin requirements for a stable manufacturing window to ensure stable RRAM operation and yield. Therefore, an alternative structure and method of fabrication is needed to meet demand for a higher-density RRAM memory. The MIS RRAM bit cell circuit 200 is formed in a FEOL process that integrates fabrication of a MIS RRAM device and a corresponding access transistor. The doped region 206 of the first semiconductor structure 208 comprises an N+ or P+ doped region, doped with N+ or P+ particles, according to a material of the semiconductor structure. The metal layer 212 is formed by disposing work function layers, such as titanium nitride (TiN), tantalum nitride (TaN), or titanium aluminum nitride (TiAlN), for example, to a thickness in the range of 1-10 nanometers (nm). The MIS RRAM device 202, having the bottom electrode 204 comprising the doped region 206 of the first semiconductor structure 208 and the top electrode 210 comprising the metal layer 212, overcomes the limitations encountered in conventional MIM RRAM devices. The MIS RRAM device 202 can therefore be scaled in accordance with the dimensions of a transistor gate, for example, for which advancements are ongoing. In this regard, a MIS RRAM array formed of MIS RRAM devices can achieve higher density than a MIM RRAM array, which lowers area, cost, and power consumption.

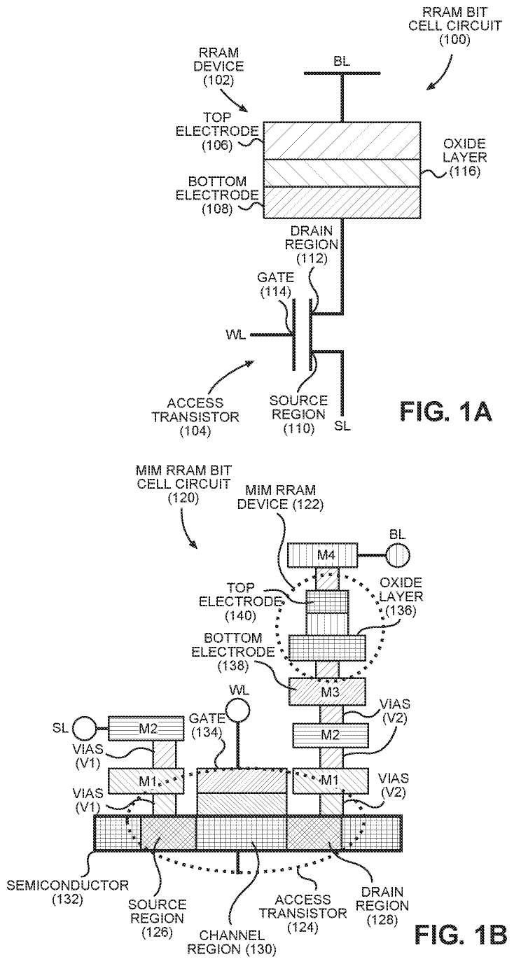

The MIS RRAM bit cell circuit 200 is suitable to be employed in a MIS RRAM array for a memory system for storing data. Although the structure of the MIS RRAM bit cell circuit 200 differs from the structure of the RRAM bit cell circuit 100 in FIG. 1A, operation of the MIS RRAM bit cell circuit 200 corresponds to operation of the RRAM bit cell circuit 100, as described above. Data is stored in the MIS RRAM device 202 based on a voltage applied between the bottom electrode 204 and the top electrode 210 under the control of the access transistor 214. The access transistor 214 turns on in response to a word line voltage V_{WL} on a gate 220 of the access transistor 214. The MIS RRAM device 202 stores data as one of a low-resistance state (LRS) and a high-resistance state (HRS) of the oxide layer 211 disposed on the doped region 206. The oxide layer 211 is configured to be reversibly switched between the LRS or the HRS in response to a voltage differential between a source line voltage V_{SL} supplied to the bottom electrode 204 and a bit line voltage V_{BL} supplied to the top electrode 210. The MIS RRAM device 202 is “set” to the LRS or “reset” to the HRS, or switched between the LRS and HRS in response to the access transistor 214 being turned on by the word line voltage V_{WL}. The LRS corresponds to a state in which a filament, which is a low-resistance path between the bottom electrode 204 and the top electrode 210, is formed by a cluster of defects or vacancies in the oxide layer 211. The HRS corresponds to a state in which the filament in the oxide layer 211 is dispersed or disconnected in response to a second difference in voltage. The LRS and HRS may be used to store binary data in the MIS RRAM bit cell circuit 200, where the LRS and HRS correspond to the binary values of “0” and “1,” respectively, or “1” and “0,” respectively, for example.

With continuing reference to FIG. 2, the MIS RRAM device 202 is formed in the first semiconductor structure 208, and the access transistor 214 is formed in the second semiconductor structure 218. The first and second semiconductor structures 208 and 218 are both formed on a substrate 224, but are separated from each other by a shallow trench isolation (STI) region 226 formed in the substrate 224. For isolation, the structures of the MIS RRAM device 202 and the access transistor 214 are covered by lower, middle, and upper dielectric layers 228, 230, and 232, respectively. Contacts are provided to the MIS RRAM device 202 and the access transistor 214 through the lower, middle, and upper dielectric layers 228, 230, and 232. Beginning with the MIS RRAM device 202, the structures of the MIS RRAM bit cell circuit 200 are now described.

The MIS RRAM device 202 includes the top electrode 210, the oxide layer 211, and the bottom electrode 204 formed on the first semiconductor structure 208. The top electrode 210 is coupled to the bit line BL by an upper top electrode contact C_{TEU} through the upper dielectric layer 232, and a lower top electrode contact C_{TEL} through the middle dielectric layer 230. Thus, the bit line voltage V_{BL} may be provided to the top electrode 210 through the upper top electrode contact C_{TEU} and the lower top electrode contact C_{TEL}. The top electrode 210 is formed between side spacers SS(1) and SS(2) by a top electrode core 210C surrounded by an electrode outer layer 210S. The electrode outer layer 210S is formed by the metal layer 212 used to form the gate 220 of the access transistor 214. The top electrode core 210C is a conductive fill metal that may be the same or a different conductive metal than the metal layer 212. By forming the top electrode 210 in FIG. 2 by a FEOL process, the dimensions of the top electrode 210 of the MIS RRAM device 202 can be much smaller than the top electrode of a conventional MIM RRAM device.

The top electrode 210 is separated from the side spacers SS(1) and SS(2), and also from the doped region 206 (i.e., bottom electrode 204), by the oxide layer 211. The oxide layer 211 between the top electrode 210 and the bottom electrode 204 is subjected to an electric field based on a voltage between the top and bottom electrodes 210 and 204. Thus, a conductive filament can be formed by a chain or cluster of mobile defects caused by mobile ions in the oxide layer 211 in response to an applied voltage to store data in the LRS or the HRS, as previously discussed.

The side spacers SS(1) and SS(2) are separated from the doped region 206 by portions of an insulation layer 238. The doped region 206 is formed in the first semiconductor structure 208, which may include a surface 225 (e.g., planar) of the substrate 224. The first semiconductor structure 208 may alternatively be a fin structure, extending in the X-axis direction in FIG. 2, formed on or above the substrate 224. In this example, the surface 225 may be a top surface of a fin structure extending in the X-axis and Y-axis directions, and the fin structure may include opposing side surfaces each extending in the X-axis and Z-axis directions (i.e., orthogonal to the top surface) in the example in FIG. 2. Thus, the doped region 206 of the first semiconductor structure 208 in the example in which the first semiconductor structure 208 is a fin structure includes a doped portion of the top surface of the fin structure and opposing doped portions of the opposing sides surfaces of the fin structure (not shown). In the cross-sectional side view of FIG. 2, the oxide layer 211 is shown disposed on the surface 225 of the substrate 224, which may be a planar surface or may be a top surface of a fin structure. In an example in which the first semiconductor structure 208 is a fin structure, the oxide layer 211, which may comprise Hafnium Oxide (HfO2), is disposed over the doped region 206 on the top surface and opposing side surfaces of the fin structure. A fin structure of the first semiconductor structure 208 may correspond to a fin structure of a fin FET (FinFET), for example. In addition, the top electrode 210 in such example may be disposed over the oxide layer 211 on the top surface and opposing side surfaces of the first semiconductor structure 208. Whether the first semiconductor structure 208 is planar, fin shaped, or shaped otherwise, dimensions of the top electrode 210 formed by the doped region 206 of the substrate 224 may correspond to the dimensions of a transistor gate. Thus, the bottom electrode 204 can be made much smaller than a bottom electrode of a conventional MIM RRAM device.

The first and second nodes 240A and 240B, formed on either end of the doped region 206, are conductive nodes that may be regions of epitaxial growth. A voltage can be supplied to the bottom electrode 204 through either of the first and second nodes 240A and 240B. In this regard, first and second bottom electrode contacts C_{BE1} and C_{BE2} are formed on the first node 240A and the second node 240B, respectively, through the middle and lower dielectric layers 230 and 228. In the MIS RRAM bit cell circuit 200, the first bottom electrode contact C_{BE1} is coupled to a coupling structure 242, which extends through the upper dielectric layer 232, over the STI region 226, and back through the upper dielectric layer 228 to couple to the access transistor 214. The coupling structure 242 is configured to couple a second source/drain region SD2 of the access transistor 214 to the bottom electrode 204 of the MIS RRAM device 202. The second bottom electrode contact C_{BE2} is available as an additional or alternative contact for coupling a voltage to the bottom electrode 204 of the MIS RRAM device 202, but is unused in the MIS RRAM bit cell circuit 200 in FIG. 2.

The access transistor 214 is formed on the second semiconductor structure 218. The access transistor 214 includes a first source/drain region SD1 of the second semiconductor structure 218 configured to couple to a source line SL to receive the source line voltage V_{SL}. The access transistor 214 also includes the second source/drain region SD2 coupled to the bottom electrode 204 of the MIS RRAM device 202. The access transistor 214 includes a channel region 244 disposed between the first source/drain region SD1 and the second source/drain region SD2. In other words, the first and second source/drain regions SD1 and SD2 are formed at respective end portions 244L and 244R of the channel region 244. The access transistor 214 includes the gate 220 comprising a metal layer 212 disposed on the channel region 244 and is configured to be coupled to a word line WL to receive the word line voltage V_{WL}. The access transistor 214 is configured to supply the source line voltage V_{SL} to the bottom electrode 204 in response to the word line voltage V_{WL}. The first and second source/drain regions SD1 and SD2 may be regions of epitaxial growth. The second source/drain region SD2 is coupled to the coupling structure 242 by a second source/drain contact C_{SU2} through the middle and lower dielectric layers 230 and 228. The first source/drain region SD1 is coupled to the source line SL through the lower and middle dielectric layers 228 and 230 by a lower first source/drain contact C_{SD1L} and through the upper dielectric layer 232 by an upper first source/drain contact C_{SD1U}.

The channel region 244 of the second semiconductor structure 218 may be a surface (e.g., planar) of the substrate 224 or a fin structure formed on or above the substrate 224. Thus, the gate 220 may be formed on a top surface and side surfaces, if any, of the channel region 244. The gate 220 includes a gate outer layer 220S formed by the metal layer 212 surrounding a gate core 220C. The gate 220 is isolated from the channel region 244 by a gate dielectric layer 246, which may be a high-K dielectric such as Hafnium Oxide (HfO2). The gate 220 is formed between side spacers SS(3) and SS(4), which are separated from the channel region 244 by portions of the insulation layer 238. The gate 220 is coupled to the word line WL by a lower gate contact C_{GL} and an upper gate contact C_{GU} such that the word line voltage V_{WL} may be supplied to the gate 220 to control the access transistor 214.

Based on a voltage difference between the source line voltage V_{SL} coupled to the bottom electrode 204 and the bit line voltage V_{BL} coupled to the top electrode 210, the MIS RRAM bit cell circuit 200 may be used to store data by setting the MIS RRAM device 202 to a LRS or resetting the MIS RRAM device 202 to a HRS. For example, the oxide layer 211 may be set to the LRS by a first voltage between the bottom electrode 204 and the top electrode 210, and the oxide layer 211 may be set to the HRS by a second voltage between the bottom electrode 204 and the top electrode 210. The MIS RRAM bit cell circuit 200 may also be used to read the stored data value. In this regard, a voltage is applied to the oxide layer 211 without switching the LRS or HRS in response to the word line voltage V_{WL} supplied on the word line WL, and a current passed through the oxide layer 211 in a read operation is employed to determine whether the oxide layer 211 is in the LRS or the HRS. The MIS RRAM bit cell circuit 200 as shown in FIG. 2 is formed in a FEOL CMOS-compatible process in which formation of the MIS RRAM device 202, including the bottom electrode 204 formed in the doped region 206 of the first semiconductor structure 208 and the top electrode 210 formed by the metal layer 212, is integrated with formation of the access transistor 214 configured to control supply of a voltage to the bottom electrode 204 in the second semiconductor structure 218. In this regard, the MIS RRAM device 202 may be formed with dimensions corresponding to a transistor gate length, and there is potential for further scaling with advancements in CMOS techniques. A MIS RRAM array formed by rows and columns of the MIS RRAM bit cell circuit 200 can have a higher integration density than a conventional MIM RRAM array, resulting in smaller area and lower cost. Also, due to the smaller size of the MIS RRAM device 202, a MIS RRAM array would have reduced power consumption in comparison to a conventional MIM RRAM device.

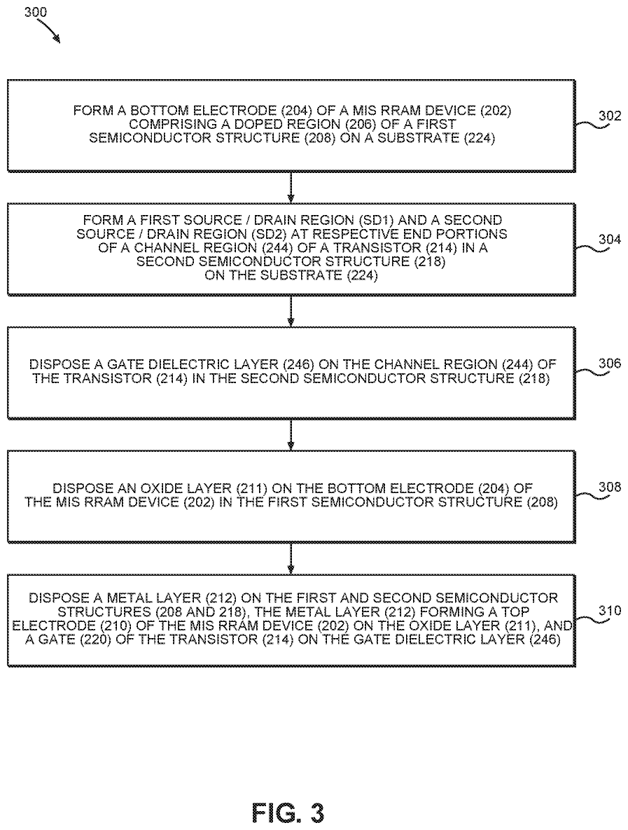

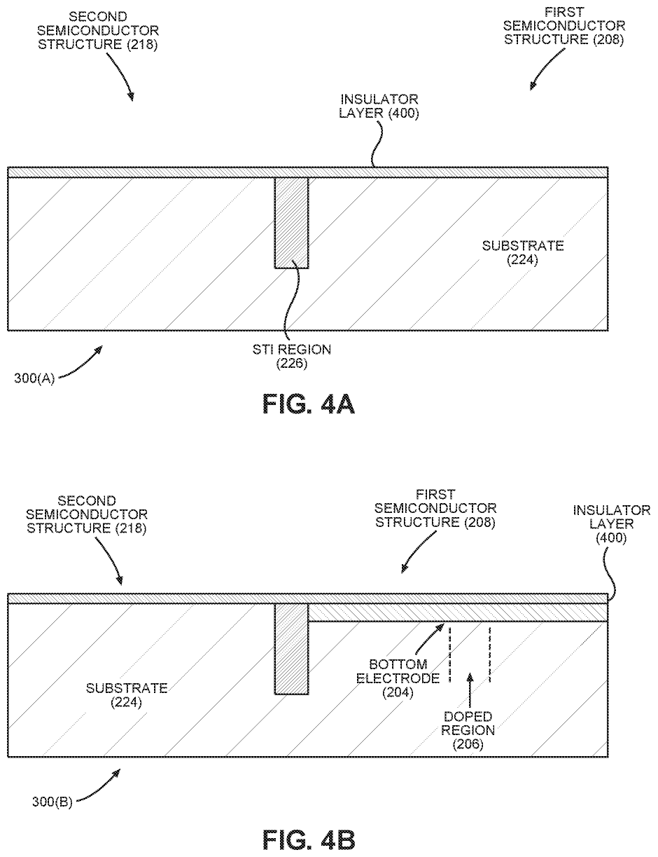

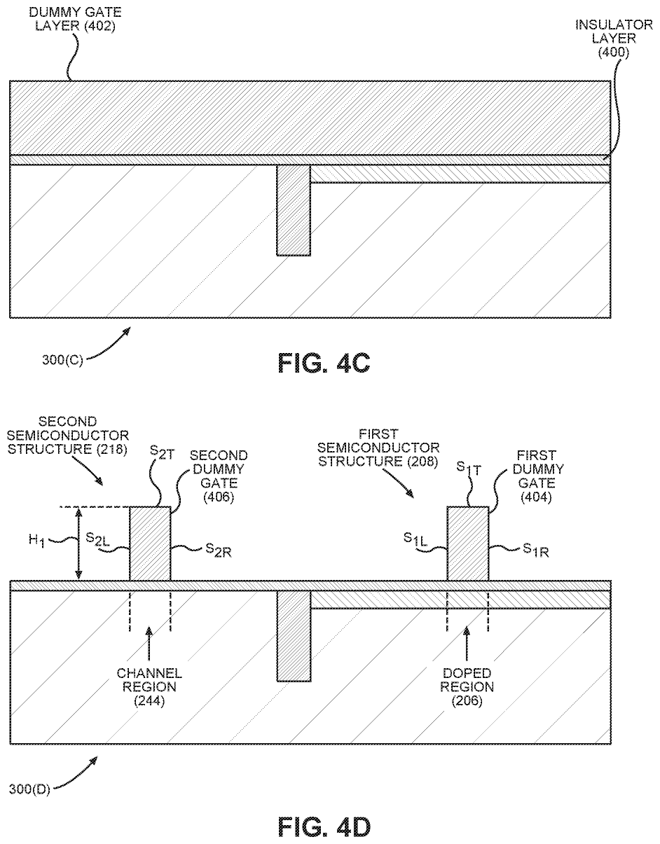

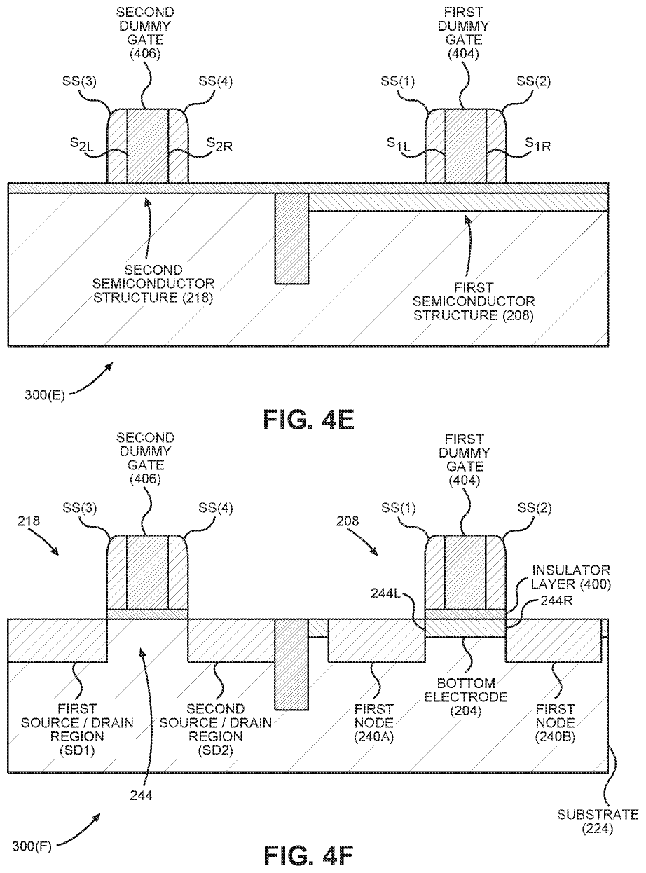

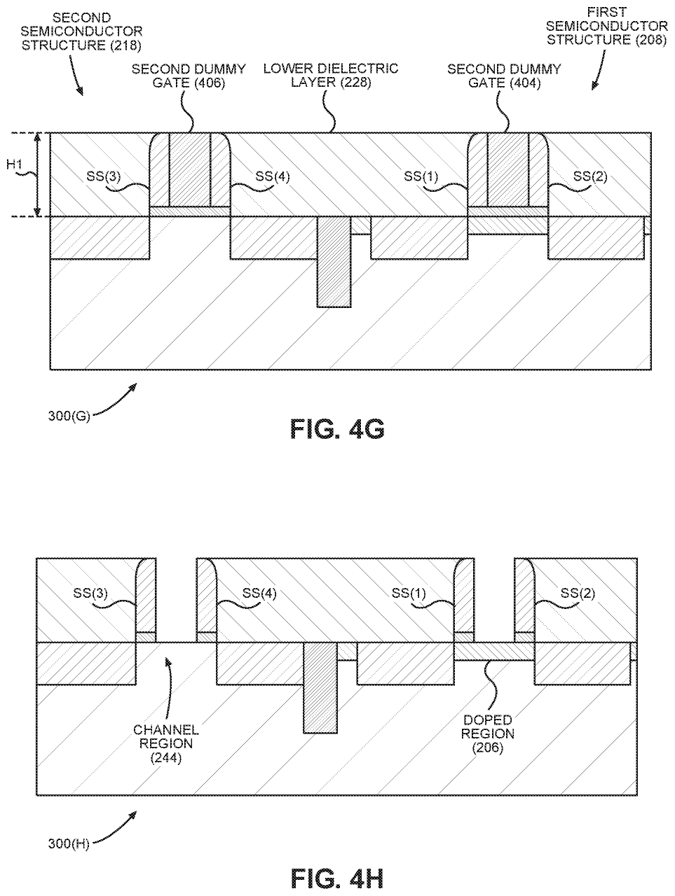

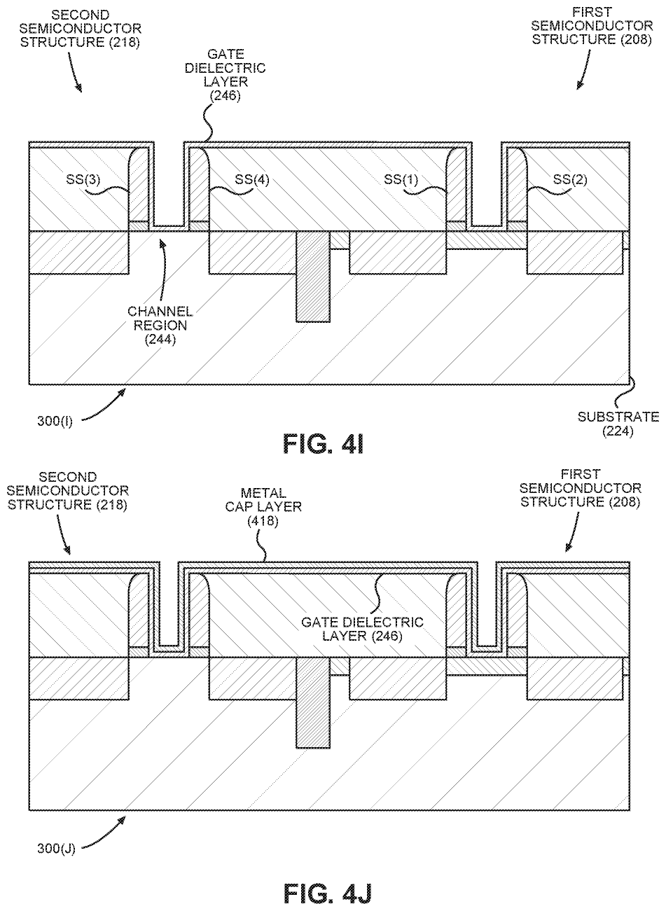

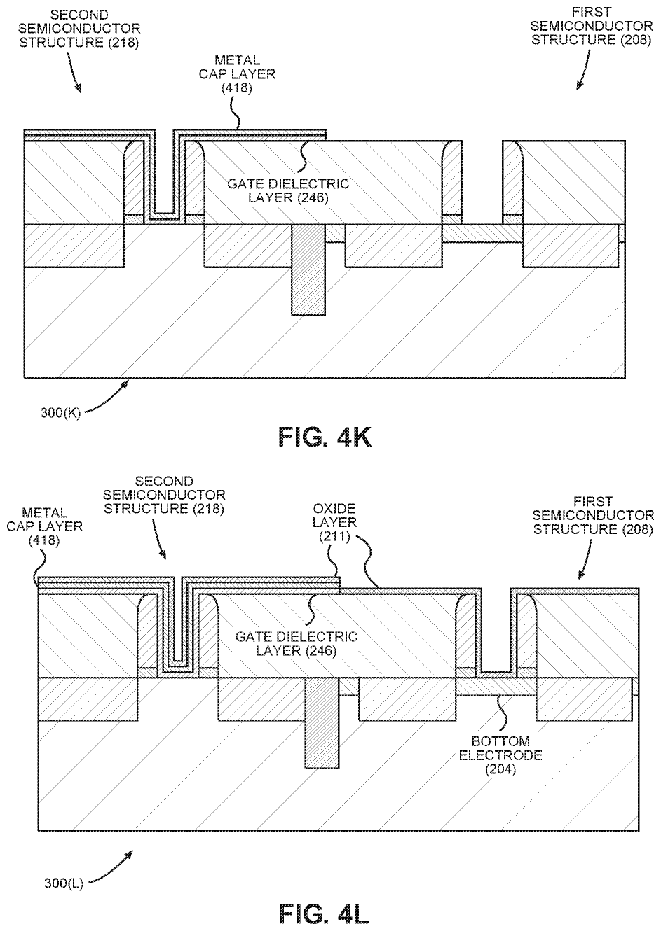

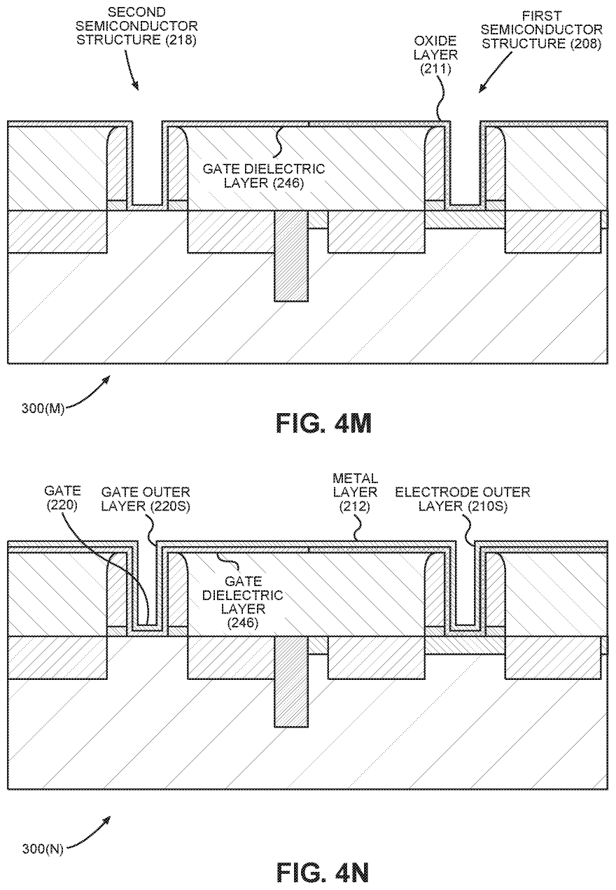

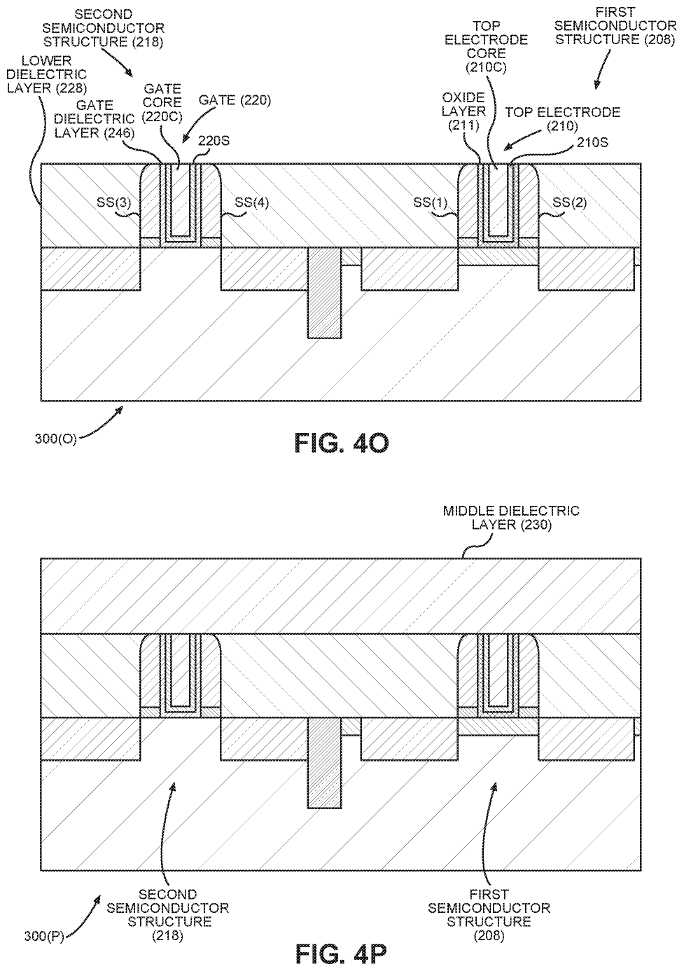

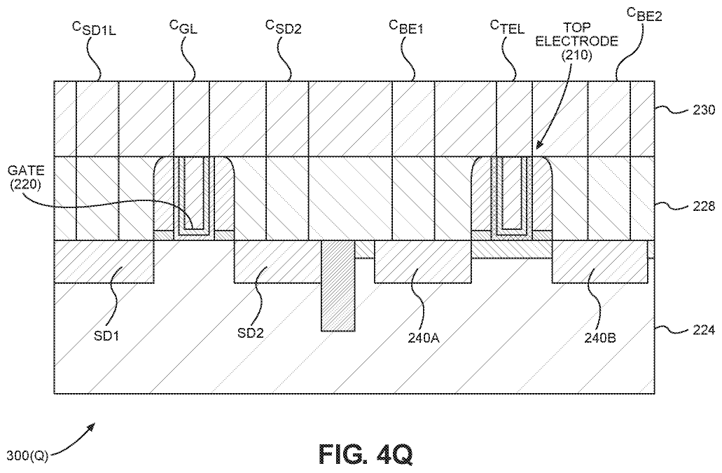

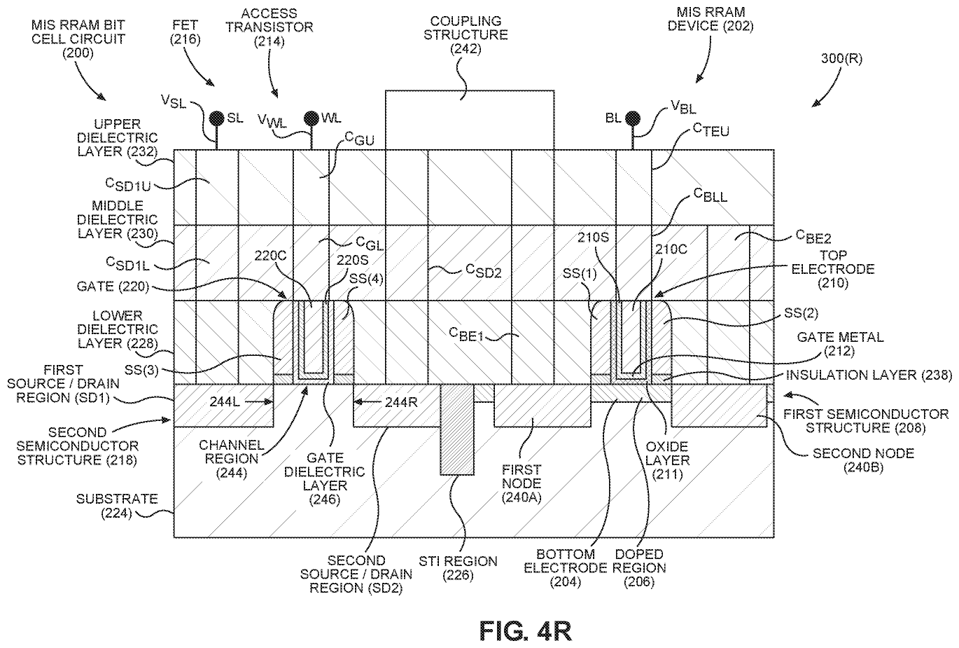

FIG. 3 is a flowchart illustrating an exemplary process 300 of fabricating the MIS RRAM bit cell circuit 200 in FIG. 2, including forming a MIS RRAM device 202 in a first semiconductor structure 208 and an access transistor 214 in a second semiconductor structure 218 together in a CMOS-compatible FEOL process. The process 300 is described with reference to fabrication stages 300(A)-300(R) illustrated in FIGS. 4A-4R, respectively.

FIG. 4A illustrates an exemplary fabrication stage 300(A) for fabricating the MIS RRAM bit cell circuit 200 in FIG. 2, including forming the STI region 226 disposed between the first semiconductor structure 208 and the second semiconductor structure 218 in the substrate 224. The STI region 226 in the example in FIG. 4A has a depth in the range of 0.2 to 0.5 micrometers (μm). Fabrication stage 300(A) also includes forming an insulator layer 400 on the first semiconductor structure 208 and the second semiconductor structure 218 of the substrate 224. In the example in FIG. 4A, forming the insulator layer 400 may include forming a silicon dioxide (SiO2) layer having a thickness in the range of two (2) to three (3) nanometers (nm) on a silicon (Si) substrate 224, for example.

FIG. 4B illustrates an exemplary fabrication stage 300(B) for fabricating the MIS RRAM bit cell circuit 200 in FIG. 2, including forming a bottom electrode 204 of the MIS RRAM device 202 comprising a doped region 206 of the first semiconductor structure 208 on the substrate 224 (FIG. 3, block 302), which may include implanting ions through the insulator layer 400. Forming the bottom electrode 204 may include implanting N+ions in the substrate 224 in the first semiconductor structure 208 to form an N+ doped region 206 to correspond to an N-well region formed for an N-type access transistor 214 (not shown) in the second semiconductor structure 218. Forming the bottom electrode 204 may alternatively include implanting P+ions in the substrate 224 in the first semiconductor structure 208 to form a P+ doped region 206 to correspond to a P-well region being formed for a P-type access transistor 214 in the second semiconductor structure 218. The doped region 206 may be formed by ions implanted to a concentration of 10²⁰/cm³ and have a thickness of 0.1 μm to 1.0 μm. The second semiconductor structure 218 is appropriately doped for formation of the access transistor 214, according to CMOS FEOL processes.

FIG. 4C illustrates an exemplary fabrication stage 300(C) for fabricating the MIS RRAM bit cell circuit 200 in FIG. 2, including forming a dummy gate layer 402 on the insulator layer 400. Forming the dummy gate layer 402 in this example may include depositing poly-silicon (Poly-Si) to a depth of 100 nm. FIG. 4D illustrates an exemplary fabrication stage 300(D) for fabricating the MIS RRAM bit cell circuit 200 in FIG. 2, including forming a first dummy gate 404 on the first semiconductor structure 208 and a second dummy gate 406 on the second semiconductor structure 218. Forming the first and second dummy gates 404 and 406 includes employing photolithography and etching to remove portions of the dummy gate layer 402 that are not in the doped region 206 of the first semiconductor structure 208 and in the channel region 244 where the gate 220 (not shown) is to be formed in the second semiconductor structure 218. The first and second dummy gates 404 and 406 are formed to have a first height H1 in the range of 25-35 nm above the insulator layer 400 and a width in the range of 10-20 nm. The first dummy gate 404 has a top surface S_{1T} and opposing side surfaces S_{1L}, and S_{1R}. The second dummy gate 406 has a top surface S_{2T} and opposing side surfaces S_{2L} and S_{2R}.

FIG. 4E illustrates an exemplary fabrication stage 300(E) for fabricating the MIS RRAM bit cell circuit 200 in FIG. 2, including forming first and second side spacers SS(1) and SS(2) on the opposing side surfaces S_{1L}, S_{1R} of the first dummy gate 404 and third and fourth side spacers SS(3) and SS(4) on the opposing side surfaces S_{2L}, S_{2R} of the second dummy gate 406. The side spacers SS(1)-SS(4) in the example in FIG. 4E are formed by depositing a conformal layer of SiO2, SiON, or SiN, for example, to a thickness in the range of 10 to 20 nm and etching the side spacers SS(1)-SS(4) (e.g., anisotropic etching) from all surfaces on the first and second semiconductor structures 208 and 218, except for the side surfaces S_{1L}, S_{1R} and S_{2L}, S_{2R} of the first and second dummy gates 404 and 406, with a remaining thickness of 10 nm. The sides spacers SS(1)-SS(4) are formed to have the height H1 corresponding to the height H1 of the first and second dummy gates 404 and 406.

FIG. 4F illustrates an exemplary fabrication stage 300(F) for fabricating the MIS RRAM bit cell circuit 200 in FIG. 2, including removing portions of the insulator layer 400 that are not covered by the first and second dummy gates 404 and 406 or by the sides spacers SS(1)-SS(4). In the example shown in FIG. 4F, removing the portions of the insulator layer 400 includes selectively etching the insulator layer 400 on both sides of the first dummy gate 404 on the first semiconductor structure 208 and etching the insulator layer 400 on both sides of the second dummy gate 406 on the second semiconductor structure 218. Fabrication stage 300(F) further includes forming a first node 240A and a second node 240B on respective sides of the bottom electrode 204 in the first semiconductor structure 208 and a forming a first source/drain region SD1 and a second source/drain region SD2 at respective end portions 244L and 244R of the channel region 244 of the access transistor 214 in the second semiconductor structure 218 (FIG. 3, block 304). The first node 240A and the second node 240B are each electrically coupled to the bottom electrode 204. The first node 240A, the second node 240B, the first source/drain region SD1, and the second source/drain region SD2 may be regions of epitaxial growth of, for example, an N+epitaxial source/drain (eSD) material or a P+epitaxial silicon-germanium (eSiGe) material, in a known FEOL process after removing portions of the substrate 224. Thus, forming the first node 240A, the second node 240B, the first source/drain region SD1, and the second source/drain region SD2 includes growing epitaxial regions in the first and second semiconductor structures 208 and 218.

FIG. 4G illustrates an exemplary fabrication stage 300(G) for fabricating the MIS RRAM bit cell circuit 200 in FIG. 2, including disposing a lower dielectric layer 228 to the first height H1 on the first and second semiconductor structures 208 and 218. Forming the lower dielectric layer 228 may include depositing an oxide layer having a depth in the range of 100 to 150 nm and planarizing the lower dielectric layer 228 to have the height H1 corresponding to the first and second dummy gates 404 and 406 and the side spacers SS(1)-SS(4) such that the first and second dummy gates 404 and 406 are exposed. The planarizing may be achieved by a chemical mechanical polishing (CMP), for example. FIG. 4H illustrates an exemplary fabrication stage 300(H) for fabricating the MIS RRAM bit cell circuit 200 in FIG. 2, including removing the first dummy gate 404 above the doped region 206 between the first and second side spacers SS(1) and SS(2) and removing the second dummy gate 406 above the channel region 244 between the third and fourth side spacers SS(3) and SS(4). Removing the first and second dummy gates 404 and 406 may include selective etching.

FIG. 4I illustrates an exemplary fabrication stage 300(I) for fabricating the MIS RRAM bit cell circuit 200 in FIG. 2, including disposing a gate dielectric layer 246 on the channel region 244 of the access transistor 214 in the second semiconductor structure 218 (FIG. 3, block 306). Forming the gate dielectric layer 246 in the example in FIG. 4J includes depositing a conformal high-K (i.e., high dielectric constant K) gate dielectric material, such as Hafnium Oxide (HfO2), between the third and fourth side spacers SS(3) and SS(4) on the second semiconductor structure and 218 and employing a high temperature treatment to improve the high-K quality. The conformal high-K gate dielectric material is deposited on the substrate 224 in the channel region 244 of the second semiconductor structure 218 and also on inner surfaces of the side spacers SS(3) and SS(4) between the side spacers SS(3) and SS(4). The gate dielectric layer 246 is similarly disposed on the doped region of the substrate 224 in the first semiconductor structure 208 and on inner surfaces of the side spacers SS(1) and SS(2) between the side spacers SS(1) and SS(2).

FIG. 4J illustrates an exemplary fabrication stage 300(J) for fabricating the MIS RRAM bit cell circuit 200 in FIG. 2, including forming a metal cap layer 418 on the gate dielectric layer 246 on the first and second semiconductor structures 208 and 218. Forming the metal cap layer 418 may include depositing a layer of TaN, for example. FIG. 4K illustrates an exemplary fabrication stage 300(K) for fabricating the MIS RRAM bit cell circuit 200 in FIG. 2, including removing the gate dielectric layer 246 and the metal cap layer 418 from the first semiconductor structure 208. The fabrication stage 300(K) may include using a photolithographic process to form a protective cover (not shown) over the second semiconductor structure 218, etching the gate dielectric layer 246 and the metal cap layer 418 from all surfaces of the first semiconductor structure 208, and removing the protective cover from the second semiconductor structure 218.

FIG. 4L illustrates an exemplary fabrication stage 300(L) for fabricating the MIS RRAM bit cell circuit 200 in FIG. 2, including disposing the oxide layer 211 on the bottom electrode 204 of the MIS RRAM device 202 in the first semiconductor structure 208 (FIG. 3, block 308). In the example herein, disposing the oxide layer 211 includes depositing the oxide layer 211, which is another layer of high-K Hafnium Oxide (HfO2), on the first and second semiconductor structures 208 and 218. FIG. 4M illustrates an exemplary fabrication stage 300(M) for fabricating the MIS RRAM bit cell circuit 200 in FIG. 2, including removing the oxide layer 211 and the metal cap layer 418 from the second semiconductor structure 218. The fabrication stage 300(M) may include using a photolithographic process to form a protective cover (not shown) over the first semiconductor structure 208 and etching the oxide layer 211 and the metal cap layer 418 from the second semiconductor structure 218, leaving the gate dielectric layer 246, and removing the protective cover from the first semiconductor structure 208.

FIG. 4N illustrates an exemplary fabrication stage 300(N) for fabricating the MIS RRAM bit cell circuit 200 in FIG. 2, including disposing a metal layer 212 on the first and second semiconductor structures 208 and 218, the metal layer 212 forming a top electrode 210 of the MIS RRAM device 202 on the oxide layer 211 and a gate 220 of the access transistor 214 on the gate dielectric layer 246 (FIG. 3, block 310). The gate outer layer 220S and the electrode outer layer 210S are both formed by depositing the metal layer 212, which may comprise a metal gate work function layer comprising TiN, TaN, or TiAlN, for example, to a thickness in the range of 1-10 nm.

FIG. 4O illustrates an exemplary fabrication stage 300(0) for fabricating the MIS RRAM bit cell circuit 200 in FIG. 2, including disposing a fill metal on the gate outer layer 220S to form the gate core 220C and on the electrode outer layer 210S to form the top electrode core 210C. The fill metal fills the space between the first and second side spacers SS(1) and SS(2) and the space between the third and fourth side spacers SS(3) and SS(4). Fabrication stage 300(0) also includes employing CMP to remove portions of the gate dielectric layer 246, metal layer 212, and fill metal from the lower dielectric layer 228 on both sides of the gate 220 on the second semiconductor structure 218. CMP is also employed to remove portions of the oxide layer 211, metal layer 212, and fill metal from the lower dielectric layer 228 on both sides of the top electrode 210 on the first semiconductor structure 208.

FIG. 4P illustrates an exemplary fabrication stage 300(P) for fabricating the MIS RRAM bit cell circuit 200 in FIG. 2, including forming a middle dielectric layer 230 on the first and second semiconductor structures 208 and 218 to provide isolation for the first and second semiconductor structures 208 and 218. Forming the middle dielectric layer 230 includes depositing the middle dielectric layer 230 to a thickness in the range of 200 nm to 500 nm.

FIG. 4Q illustrates an exemplary fabrication stage 300(Q) for fabricating the MIS RRAM bit cell circuit 200 in FIG. 2, including forming contacts through the middle dielectric layer 230 and the lower dielectric layer 228 on the first node 240A, the top electrode 210, the second node 240B, the first source/drain region SD2, the gate 220, and the second source/drain region SD2. In particular, as shown in FIG. 4Q, the contact C_{BE1} is formed on the first node 240A, the lower top electrode contact C_{TEL} is formed on the top electrode 210, the contact C_{BE2} is formed on the second node 240B, the lower first source/drain contact C_{SD1L} is formed on the first source/drain region SD1, the lower gate contact C_{GL} is formed on the gate 220, and the contact C_{SD2} is formed on the second source/drain region SD2. In fabrication stage 300(Q), the contacts C_{BE1}, C_{TEL}, C_{BE2}, C_{SD1L}, C_{GL}, and C_{SD2} are formed through the middle dielectric layer 230 and the lower dielectric layer 228 by employing a photolithographic process in which openings are formed and then filled with a contact material, such as metal.

FIG. 4R illustrates an exemplary fabrication stage 300(R) for fabricating the MIS RRAM bit cell circuit 200 in FIG. 2, including forming a coupling structure 242 to couple the first node 240A to the second source/drain region SD2. The coupling structure 242 couples the contact C_{BE1} on the first node 240A to the contact C_{SD2} on the second source/drain region SD2. Forming the coupling structure 242 includes forming an upper dielectric layer 232 on the first and second semiconductor structures 208 and 218 over the middle dielectric layer 230. In fabrication stage 300(R), an upper first source/drain contact C_{SD1U} is formed in the upper dielectric layer 232 to couple to the contact C_{SD1L} and to the source line SL, an upper gate contact C_{GU} is formed in the upper dielectric layer 232 to couple to the gate contact C_{GL} and to the word line WL, and an upper top electrode contact C_{TEU} is formed in the upper dielectric layer 232 to couple to the lower top electrode contact C_{E} to the bit line BL. The contacts C_{SD1U}, C_{GU}, and C_{TEU} and the coupling structure 242 are formed in the upper dielectric layer 232 by employing a photolithographic process to form openings that are filled with a contact material, such as metal. Forming the coupling structure 242 also includes forming metal on the upper dielectric layer 232 to couple the contacts C_{BE1} and C_{SD2}. Optionally, a second contact (not shown) may be formed in the upper dielectric layer 232 to couple to the contact C_{BE2} to provide an extra (e.g., second) contact to the bottom electrode 204 through the second node 240B.

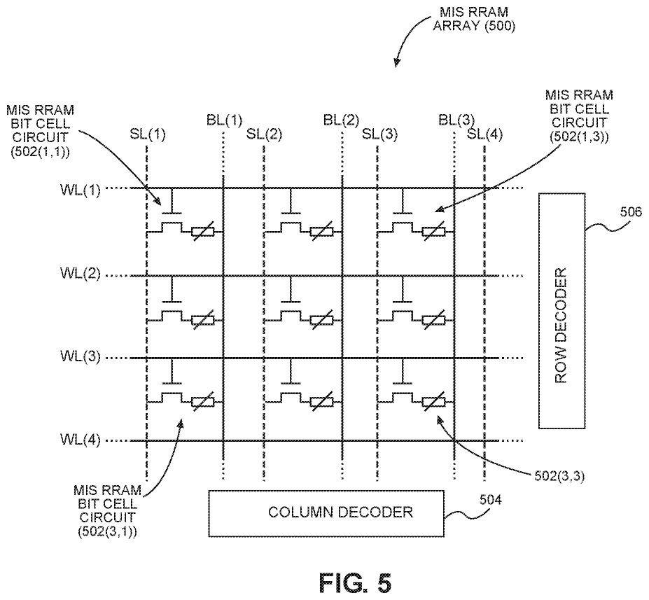

FIG. 5 is a schematic diagram of an exemplary MIS RRAM array 500 comprising a plurality of MIS RRAM bit cell circuits 502(1,1)-502(M,N) organized in rows and columns. The MIS RRAM array 500 in FIG. 5 illustrates only MIS RRAM bit cell circuits 502(1,1)-502(3,3), but the MIS RRAM array 500 has M rows and N columns including M×N MIS RRAM bit cell circuits 502(M,N), where M and N may be any integer, such as 512, 1024, 2048, etc. The MIS RRAM array 500 includes access circuitry for accessing the MIS RRAM bit cell circuits 502(1,1)-502(M,N), including a Column Decoder 504 configured to provide the word line voltage V_{WL} on word lines WL(1)-WL(M) and a Row Decoder 506 configured to provide the source line voltage V_{SL} on source lines SL(1)-SL(N) and the bit line voltage V_{BL} on bit lines BL(1)-BL(N) to read or write data in at least one of the plurality of MIS RRAM bit cell circuits 502(1,1)-502(M,N). The MIS RRAM bit cell circuits 502(1,1)-502(M,N) may each include the MIS RRAM bit cell circuit 200 of FIG. 2 and FIG. 4R, which includes the MIS RRAM device 202 in which the top electrode 210 is formed in the metal layer 212 over the bottom electrode 204 disposed in the doped region 206 of the first semiconductor structure 208, allowing dimensions of the MIS RRAM device 202 to be scaled down to the dimensions of a transistor gate, such as the gate 220 of the access transistor 214.

A MIS RRAM bit cell circuit that includes a MIS RRAM device in which a top electrode is formed in a metal layer over a bottom electrode disposed in a semiconductor structure, allowing dimensions of the electrodes of the MIS RRAM device to be scaled down to the dimensions of a transistor gate, because the MIS RRAM device can be fabricated with the access transistor in a CMOS-compatible process, as illustrated in any of FIGS. 2 and 4R, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

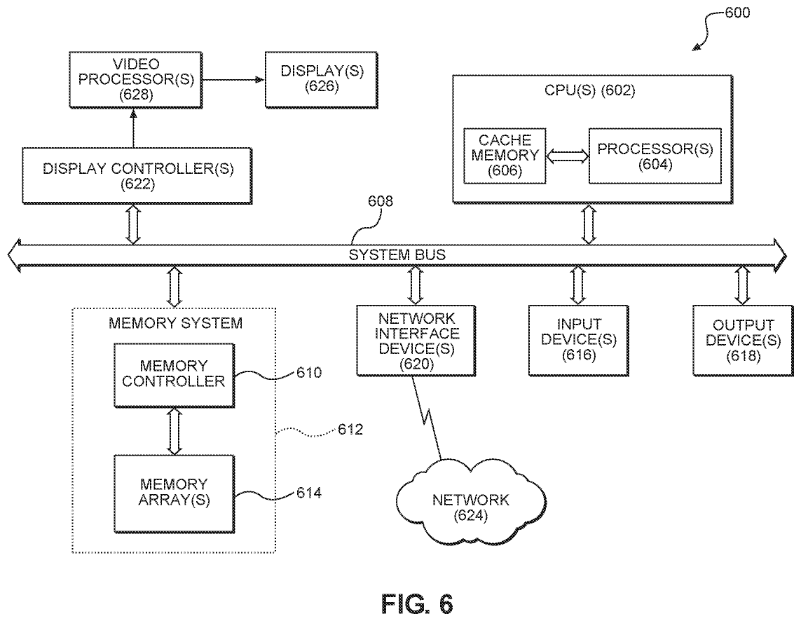

In this regard, FIG. 6 illustrates an example of a processor-based system 600 including a MIS RRAM bit cell circuit that includes a MIS RRAM device in which a top electrode is formed in a metal layer over a bottom electrode disposed in a semiconductor structure, allowing dimensions of the electrodes of the MIS RRAM device to be scaled down to the dimensions of a transistor gate, because the MIS RRAM device can be fabricated with the access transistor in a CMOS-compatible process, including, but not limited to the MIS RRAM bit cell circuit 200 in FIGS. 2 and 4R, and according to any aspects disclosed herein. In this example, the processor-based system 600 includes one or more central processor units (CPUs) 602, which may also be referred to as CPU or processor cores, each including one or more processors 604. The CPU(s) 602 may have cache memory 606 coupled to the processor(s) 604 for rapid access to temporarily stored data. As an example, the processor(s) 604 could include a MIS RRAM bit cell circuit that includes a MIS RRAM device in which a top electrode is formed in a metal layer over a bottom electrode disposed in a doped region of a semiconductor structure, allowing dimensions of the electrodes of the MIS RRAM device to be scaled down to the dimensions of a transistor, because the MIS RRAM device can be fabricated with an access transistor in a CMOS-compatible process, as illustrated in any of FIGS. 2 and 4R, and according to any aspects disclosed herein. The CPU(s) 602 is coupled to a system bus 608 and can intercouple master and slave devices included in the processor-based system 600. As is well known, the CPU(s) 602 communicates with these other devices by exchanging address, control, and data information over the system bus 608. For example, the CPU(s) 602 can communicate bus transaction requests to a memory controller 610 as an example of a slave device. Although not illustrated in FIG. 6, multiple system buses 608 could be provided, wherein each system bus 608 constitutes a different fabric.

Other master and slave devices can be connected to the system bus 608. As illustrated in FIG. 6, these devices can include a memory system 612 that includes the memory controller 610 and one or more memory arrays 614, one or more input devices 616, one or more output devices 618, one or more network interface devices 620, and one or more display controllers 622, as examples. Each of the memory system 612, the one or more input devices 616, the one or more output devices 618, the one or more network interface devices 620, and the one or more display controllers 622 can include a MIS RRAM bit cell circuit that includes a MIS RRAM device in which a top electrode is formed in a metal layer over a bottom electrode disposed in a doped region of a semiconductor structure, allowing dimensions of the electrodes of the MIS RRAM device to be scaled down to the dimensions of a transistor, because the MIS RRAM device can be fabricated with an access transistor in a CMOS-compatible process, as illustrated in any of FIGS. 2 and 4R, and according to any aspects disclosed herein. The input device(s) 616 can include any type of input device, including, but not limited to, input keys, switches, voice processors, etc. The output device(s) 618 can include any type of output device, including, but not limited to, audio, video, other visual indicators, etc. The network interface device(s) 620 can be any device configured to allow exchange of data to and from a network 624. The network 624 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 620 can be configured to support any type of communications protocol desired.

The CPU(s) 602 may also be configured to access the display controller(s) 622 over the system bus 608 to control information sent to one or more displays 626. The display controller(s) 622 sends information to the display(s) 626 to be displayed via one or more video processors 628, which process the information to be displayed into a format suitable for the display(s) 626. The display(s) 626 can include any type of display, including, but not limited to, a cathode ray tube (CRT), a liquid crystal display (LCD), a plasma display, a light emitting diode (LED) display, etc. The display controller(s) 622, display(s) 626, and/or the video processor(s) 628 can include a MIS RRAM bit cell circuit that includes a MIS RRAM device in which a top electrode is formed in a metal layer over a bottom electrode disposed in a doped region of a semiconductor structure, allowing dimensions of the electrodes of the MIS RRAM device to be scaled down to the dimensions of a transistor, because the MIS RRAM device can be fabricated with an access transistor in a CMOS-compatible process, as illustrated in any of FIGS. 2 and 4R, and according to any aspects disclosed herein.

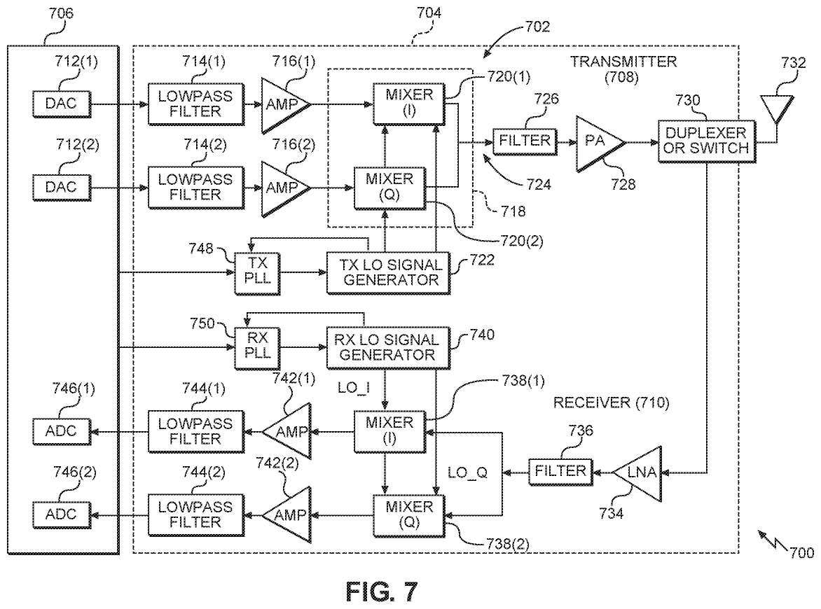

FIG. 7 illustrates an exemplary wireless communications device 700 that includes radio frequency (RF) components formed from an IC 702, wherein any of the components therein can include a MIS RRAM bit cell circuit that includes a MIS RRAM device in which a top electrode is formed in a metal layer over a bottom electrode disposed in a doped region of a semiconductor structure, allowing dimensions of the electrodes of the MIS RRAM device to be scaled down to the dimensions of a transistor, because the MIS RRAM device can be fabricated with an access transistor in a CMOS-compatible process, as illustrated in any of FIGS. 2 and 4R, and according to any aspects disclosed herein. The wireless communications device 700 may include or be provided in any of the above-referenced devices, as examples. As shown in FIG. 7, the wireless communications device 700 includes a transceiver 704 and a data processor 706. The data processor 706 may include a memory to store data and program codes. The transceiver 704 includes a transmitter 708 and a receiver 710 that support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 710. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into the I and Q analog output signals, e.g., I and Q output currents, for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals through mixers 720(1), 720(2) from a TX LO signal generator 722 to provide an upconverted signal 724. A filter 726 filters the upconverted signal 724 to remove undesired signals caused by the frequency upconversion as well as noise in a receive frequency band. A power amplifier (PA) 728 amplifies the upconverted signal 724 from the filter 726 to obtain the desired output power level and provides a transmitted RF signal. The transmitted RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Downconversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by amplifiers (AMPs) 742(1), 742(2) and further filtered by lowpass filters 744(1), 744(2) to obtain I and Q analog input signals, which are provided to the data processor 706. In this example, the data processor 706 includes Analog to Digital Converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency upconversion, while the RX LO signal generator 740 generates the I and Q RX LO signals used for frequency downconversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but, is to be accorded the widest scope consistent with the principles and novel features disclosed herein.

What is claimed is:

1. A metal-insulator-semiconductor (MIS) resistive random access memory (RRAM) (MIS RRAM) device, comprising:
a first electrode comprising a doped region of a semiconductor structure;
an oxide layer disposed on the doped region; and
a second electrode comprising a metal layer disposed on the oxide layer;
wherein the oxide layer is configured to be reversibly set in a low-resistance state (LRS) or a high-resistance state (HRS) in response to a voltage differential between the first electrode and the second electrode.

2. The MIS RRAM device of claim 1, wherein the doped region of the semiconductor structure comprises an N+ or P+ doped region.

3. The MIS RRAM device of claim 1, wherein a thickness of the doped region is in the range of 0.1-1 micrometer (μm).

4. The MIS RRAM device of claim 1, wherein the oxide layer comprises Hafnium Oxide (HfO2).

5. The MIS RRAM device of claim 1, wherein the metal layer comprises a work function layer comprising one of titanium nitride (TiN), tantalum nitride (TaN), and titanium aluminum nitride (TiAlN) having a thickness in the range of 1-10 nanometers (nm).

6. The MIS RRAM device of claim 1, wherein:
the semiconductor structure comprises a surface of a substrate.

7. The MIS RRAM device of claim 1, wherein:
the semiconductor structure comprises a fin structure disposed above a substrate, the fin structure comprising a top surface and opposing side surfaces orthogonal to the top surface; and
the doped region of the semiconductor structure comprises a doped portion of the top surface and opposing doped portions of the opposing side surfaces of the fin structure.

8. The MIS RRAM device of claim 7, wherein the oxide layer comprises Hafnium Oxide (HfO2) disposed over the doped region on the top surface and the opposing side surfaces of the fin structure.

9. The MIS RRAM device of claim 7, wherein the metal layer is disposed on the oxide layer on the top surface and the opposing side surfaces of the fin structure.

10. The MIS RRAM device of claim 1, wherein:
the oxide layer is set to the LRS by a first voltage between the first electrode and the second electrode; and
the oxide layer is set to the HRS by a second voltage between the first electrode and the second electrode.

11. A metal-insulator-semiconductor (MIS) resistive random access memory (RRAM) (MIS RRAM) bit cell circuit, comprising:
a MIS RRAM device in a first semiconductor structure on a substrate, comprising:
a first electrode comprising a doped region of the first semiconductor structure;
an oxide layer disposed on the doped region; and
a second electrode comprising a first metal layer disposed on the oxide layer; and
an access transistor in a second semiconductor structure on the substrate, comprising:
a first source/drain region of the second semiconductor structure configured to couple to a source line;
a second source/drain region of the second semiconductor structure coupled to the first electrode of the MIS RRAM device;
a channel region of the second semiconductor structure disposed between the first source/drain region and the second source/drain region; and
a gate comprising a second metal layer disposed on the channel region, the gate configured to be coupled to a word line;
wherein the access transistor is configured to supply a voltage on the source line to the first electrode in response to a voltage on the word line.

12. The MIS RRAM bit cell circuit of claim 11, wherein:
the first semiconductor structure comprises a fin structure having a top surface and opposing side surfaces orthogonal to the top surface; and
the oxide layer is disposed on the top surface and the opposing side surfaces of the fin structure.

13. The MIS RRAM bit cell circuit of claim 12, wherein:
the first metal layer of the second electrode is disposed on the oxide layer on the top surface and the opposing side surfaces of the fin structure.

14. The MIS RRAM bit cell circuit of claim 11, wherein:
the first semiconductor structure comprises a surface of the substrate.

15. The MIS RRAM bit cell circuit of claim 11, wherein:
the oxide layer is configured to be reversibly switched between a low-resistance state (LRS) and a high-resistance state (HRS) in response to a voltage differential between the first electrode and the second electrode.

16. The MIS RRAM bit cell circuit of claim 15, wherein:
a voltage is applied to the oxide layer without switching the LRS or HRS in response to the voltage supplied on the word line, and a current is passed through the oxide layer in a read operation to determine whether the oxide layer is in the LRS or the HRS.

17. The MIS RRAM bit cell circuit of claim 11, wherein:
the MIS RRAM device includes a first node and a second node each formed in the first semiconductor substrate and electrically coupled to the first electrode.

18. The MIS RRAM bit cell circuit of claim 17, wherein:
the first and second source/drain regions and the first and second nodes are regions of epitaxial growth.

19. The MIS RRAM bit cell circuit of claim 11, further comprising:
a shallow trench isolation (STI) region disposed between the first semiconductor structure and the second semiconductor structure.

20. The RRAM bit cell circuit of claim 11 integrated in an integrated circuit (IC).

21. The RRAM bit cell circuit of claim 11, integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

22. A method of fabricating a metal-insulator-semiconductor (MIS) resistive random access memory (RRAM) bit cell circuit, comprising:
forming a first electrode of a MIS RRAM device comprising a doped region of a first semiconductor structure on a substrate;
forming a first source/drain region and a second source/drain region at respective end portions of a channel region of a transistor in a second semiconductor structure on the substrate;
disposing a gate dielectric layer on the channel region of the transistor in the second semiconductor structure;
disposing an oxide layer on the first electrode of the MIS RRAM device in the first semiconductor structure; and
disposing a metal layer on the first and second semiconductor structures, the metal layer forming a second electrode of the MIS RRAM device on the oxide layer, and a gate of the transistor on the gate dielectric layer.

23. The method of claim 22, further comprising forming a coupling structure to couple the second source/drain region of the transistor to the first electrode of the MIS RRAM device.

24. The method of claim 22, wherein forming the first electrode further comprises implanting N+ or P+ material in the first semiconductor structure on the substrate to form the doped region.

25. The method of claim 23, further comprising forming a first node in the first semiconductor structure coupled to the doped region of the first semiconductor structure.

26. The method of claim 23, wherein forming the coupling structure further comprises forming the coupling structure to couple the second source/drain region of the transistor to the first node in the first semiconductor structure.

27. The method of claim 25, wherein forming the first node, the first source/drain region, and the second source/drain region further comprises growing epitaxial regions in the first and second semiconductor structures.

28. The method of claim 22, wherein the gate dielectric layer and the oxide layer are formed of Hafnium Oxide (HfO2).

29. The method of claim 22, further comprising:
disposing a dielectric layer over the first and second semiconductor structures; and
forming contacts through the dielectric layer coupled to the first source/drain region, the second source/drain region, and the gate of the transistor, and to the first electrode and the second electrode of the MIS RRAM device.

30. A memory array, comprising:
a plurality of metal-insulator-semiconductor (MIS) resistive random access memory (RRAM) (MIS RRAM) bit cell circuits each comprising:
a MIS RRAM device in a first semiconductor structure on a substrate, comprising:
a first electrode comprising a doped region of the first semiconductor structure;
an oxide layer disposed on the doped region; and
a second electrode comprising a first metal layer disposed on the oxide layer and configured to be coupled to a bit line;
an access transistor in a second semiconductor structure on the substrate, comprising:
a first source/drain region of the second semiconductor structure configured to couple to a source line;
a second source/drain region of the second semiconductor structure coupled to the first electrode of the MIS RRAM device;
a channel region of the second semiconductor structure disposed between the first source/drain region and the second source/drain region; and
a gate comprising a second metal layer disposed on the channel region, the gate configured to be coupled to a word line;
wherein the access transistor is configured to supply a voltage on the source line to the bottom electrode in response to a voltage on the word line; and
array access circuits configured to provide a word line voltage on the word line, a source line voltage on the source line, and a bit line voltage on the bit line to read or store data in at least one of the plurality of MIS RRAM bit cell circuits in response to the word line voltage.

31. The memory array of claim 30, wherein:
the oxide layer is configured to be reversibly switched between a low-resistance state (LRS) and a high-resistance state (HRS) in response to a voltage differential between the source line voltage and the bit line voltage.
